(19) United States
(12) Patent Application Publication
(10) Pub. No.: US 2008/0157836 A1
(43) Pub. Date: Jul. 3, 2008

(54) DELAY FIXING LOOP CIRCUIT FOR REDUCING SKEW BETWEEN EXTERNAL AND INTERNAL CLOCKS OR BETWEEN EXTERNAL CLOCK AND DATA, AND A CLOCK LOCKING METHOD THEREOF

(76) Inventor: Kwang Jun CHO, Seoul (KR)

Correspondence Address: LADAS & PARRY LLP, 224 SOUTH MICHIGAN AVENUE, SUITE 1600, CHICAGO, IL, 60604, US

(21) Appl. No.: 11/778,816

(22) Filed: Jul. 17, 2007

(30) Foreign Application Priority Data
Dec. 28, 2006 (KR) 10-2006-0137177

(51) Int. Cl. H03L 7/08

(52) U.S. Cl. 327/158

(57) ABSTRACT

The present invention relates to a delay fixing loop circuit including a delay fixing loop for reducing a skew between an external clock and a data, or between an external clock and an internal clock, and a clock locking method thereof. The delay fixing loop circuit includes a delay circuit delaying a reference clock in which an external clock is buffered and outputting the delayed reference clock as an internal clock; a control circuit comparing the reference clock and a phase of a feedback clock of the internal clock, and increasing or decreasing delay of the reference clock of the delay circuit according to the comparison result if a delay fixing loop is in an enable state, and decreasing delay of the reference clock of the delay circuit according to a reset signal provided from outside if the delay fixing loop is in a disable state; and a clock driver providing the internal clock of the delay circuit which is controlled by the control circuit as an output clock of the delay fixing loop.

### CROSS-REFERENCE TO RELATED APPLICATIONS

The present application claims priority to Korean patent application number 10-2006-137177 filed on Dec. 28, 2006, which is incorporated herein by reference in its entirety.

### BACKGROUND OF THE INVENTION

The present invention relates to a semiconductor memory device, and in particular, relates to a delay fixing loop circuit for reducing a skew between an external clock and an internal clock, or between an external clock and a data, and a clock locking method thereof.

Generally, a semiconductor memory device operating at a high-speed compensates a skew between an external clock and an internal clock, and thereby, data is aligned to an edge of a external clock based on the compensation, and then is outputted.

A conventional delay fixing loop for compensating a skew among the external clock, the internal clock and data can be formed as illustrated in FIG. 1.

In the conventional delay fixing loop, the external clock EXT_CLK is inputted to a clock buffer 100, and then the clock buffer 100 outputs a reference clock REF_CLK. The reference clock REF_CLK is delayed in an initialized delay line 100, and then is inputted to a replica delay unit 120. The replica delay unit 120 outputs a replica-delayed feedback clock FB_CLK.

A phase comparison unit 140 compares the replica-delayed feedback clock FB_CLK outputted from the replica delay unit 120, and the phase of the reference clock REF_CLK outputted from the clock buffer 100, and generates a delay increase signal UP and a delay decrease signal DN according to the comparison result.

The delay increase signal UP and the delay decrease signal DN generated in the phase comparison unit 140 are inputted to a delay line control unit 150, and the delay line control unit 150 generates a shift left signal SL and a shift right signal SR according to the states of the delay increase signal UP and the delay decrease signal DN.

Here, the operations of the delay line control unit 150 are controlled by an enable signal DLL_EN of the delay fixing loop for controlling the states of the delay fixing loop.

That is, if the delay fixing loop is enabled, the delay line control unit 150 is operated normally by the enable signal DLL_EN of the delay fixing loop, and if the delay fixing loop is disabled, the delay line control unit 150 is not operated by the enable signal DLL_EN of the delay fixing loop.

If the delay fixing loop is disabled, the shift left signal SL and the shift right signal SR are all disabled, the delay line 110 retains a previous state.

Further, the delay line 110 controls the reference clock REF_CLK based on the shift left signal SL and the shift right signal SR outputted from the delay line control unit 150, and the reference clock REF_CLK delay of which is controlled is outputted as an internal clock ICLK.

Here, the delay line 110 secures a predetermined amount delay for compensating a delay amount which is reduced due to a processing condition, that is, PVT(Process, Voltage, and Temperature) environment and so on and such a predetermined delay amount is called as a default delay. That is, the delay line 110 has always a delay amount much more than the default delay.

The internal clock ICLK outputted from the delay line 110 is transmitted to the phase comparison unit 140 via the replica delay unit 120, and is compared with the phase of the reference clock REF_CLK. At this time, if it is judged that the phase of the internal clock ICLK is aligned to the reference clock REF_CLK, the shift left signal SL and the shift right signal SR outputted from the delay line control unit 150 are disabled, and thus, the delay amount of the delay line 110 is fixed.

In this way, according to the fixed delay amount, the internal clock ICLK is amplified via a clock driver 170, and then is outputted as an output clock CLK_DLL of the delay fixing loop. A data output driver 190 synchronizes the data DATA with the output clock CLK_DLL of the delay fixing loop, and then outputs the synchronized data as a output data DOUT.

As explained above, the delay fixing loop synchronizes a phase and an external clock by delaying a clock by a constant time, and executes an adjustment such that the data can be synchronized with the external clock.

Such an operation of the delay fixing loop is required only when a high-speed operation is executed. In a case that a memory chip is operated at a low-speed, or a frequency is adjusted to a low level for reducing a power consumption, a valid window of data can be secured without delaying and fixing a clock internally.

In an OFF state, an conventional delay fixing loop disables the shift left signal SL and the shift right signal SR so that the delay line 110 can maintain a delay amount of a previous state.

Therefore, in an OFF state, since the delay fixing loop fixes the delay amount of the delay line 110 to the delay amount of a previous state, the data is outputted without a constant tAC(a period from input of an external clock to the time when a data output is processed.).

That is, if the conventional delay fixing loop is in an OFF state, the delay amount of the delay line 110 is sufficient large as compared with a minimum default delay, a domain margin of an output clock CLK_DLL of the delay fixing loop becomes insufficient.

In this way, if a domain margin of an output clock CLK_DLL of the delay fixing loop becomes insufficient, since a position of an output strobe can not be fixed, there is a problem that a poor product can be generated in case of a lead operation.

### SUMMARY OF THE INVENTION

Therefore, the present invention is directed to, inter alia, securing a valid window of a data by controlling a delay level of an output clock of the delay fixing loop which controls data output under a state that the delay fixing loop is in a disable state.

In accomplishing this, the delay fixing loop of the present invention includes a delay circuit delaying a reference clock in which an external clock is buffered and outputting the delayed reference clock as an internal clock; a control circuit comparing the reference clock and a phase of a feedback clock of the internal clock, and increasing or decreasing delay of the reference clock of the delay circuit according to the comparison result if a delay fixing loop is in an enable state, and decreasing delay of the reference clock of the delay circuit according to a reset signal provided from outside if the delay fixing loop is in a disable state; and a clock driver providing the internal clock of the delay circuit which is controlled by the control circuit as an output clock of the delay fixing loop.

An operation of the delay fixing loop can be disabled in response to a mode in which an operation clock frequency is changed into a low frequency.

An enable state and a disable state of the operation of the delay fixing loop can be determined according to a state of an external address provided under a state that an expansion mode register set(EMRS) is set.

A state of the reset signal can be determined according to the state of the external address provided under a state that a mode register set(MRS) is set.

Here, the control circuit can include a replica delay unit replica-delaying the internal clock and outputting it as the feedback clock; and a delay line adjustment circuit comparing the reference clock and the phase of the feedback clock of the internal clock, and increasing or decreasing delay of the reference clock of the delay circuit according to the comparison result if the delay fixing loop is in an enable state, and decreasing delay of the reference clock of the delay circuit according to the reset signal provided from outside if the delay fixing loop is in a disable state.

Here, the delay line adjustment circuit can include a phase comparison unit of a blind pull control type comparing the reference clock and the phase of the feedback clock, and generating a delay increase signal and a delay decrease signal if the delay fixing loop is in an enable state, and generating the delay decrease signal if the delay fixing loop is in a disable state; and a delay line control unit of a blind pull control type generating a shift left signal and a shift right signal corresponding to the delay increase signal and the delay decrease signal, respectively, and controlling a delay increase or a delay decrease if the delay fixing loop is in an enable state, and generating the shift right signal corresponding to the delay decrease signal according to the reset signal, and controlling the delay decrease if the delay fixing loop is in a disable state.

Here, the phase comparison unit of a blind pull control type can include a phase comparison unit comparing the reference clock and the phase of the feedback clock and outputting the delay increase signal and the delay decrease signal; and a first control unit disabling the delay increase signal, and enabling the delay decrease signal if the delay fixing loop is in a disable state.

Further, it is preferable that the comparison unit enables the delay increase signal if a rising edge of the feedback clock progresses in advance on the basis of a predetermined rising edge of the reference clock, and enables the delay decrease signal if a rising edge of the feedback clock lags behind.

Further, the delay line control unit of a blind pull control type can include a second control unit outputting a control signal according to the reset signal if the delay fixing loop is in a disable state; and a delay line control unit operating according to a state of the control signal, and generating and the shift left signal and the shift right signal as output signals of the phase comparison unit of a blind pull control type.

Further, the delay circuit includes a plurality of unit delay sections which are serially connected and are controlled by the shift left signal and the shift right signal; and only a unit delay section connected to an output stage among the plurality of unit delay sections can be enabled according to the shift right signal if the delay fixing loop is in a disable state.

A clock locking method of a delay fixing loop circuit can include a first step generating a reference clock by buffering an external clock; a second step delaying the reference clock and outputting it as an internal clock; a third step comparing the reference clock and a phase of a feedback clock of the internal clock, and increasing or decreasing delay of the reference clock of the delay circuit according to the comparison result if a delay fixing loop is in an enable state, and decreasing delay of the reference clock of the delay circuit according to a reset signal provided from outside if the delay fixing loop is in a disable state; and a fourth step providing the internal clock in which delay is controlled by operation of the delay fixing loop and the reset signal as an output clock of the delay fixing loop.

Here, it is preferable that if the delay fixing loop is in an enable state, the third step executes a step comparing the reference clock and the phase of the feedback clock, and generating a delay increase signal and a delay decrease signal; and a step generating a shift left signal and a shift right signal corresponding to the delay increase signal and the delay decrease signal, respectively, and controlling a delay increase or a delay decrease of the second step; and if the delay fixing loop is in a disable state, the third step executes a step generating the delay decrease signal; and a step generating the shift right signal corresponding to the delay decrease signal according to the reset signal, and controlling the delay decrease of the second step.

### BRIEF DESCRIPTION OF THE DRAWINGS

FIG. 1 is a block diagram showing a conventional delay fixing loop circuit.

FIG. 2 is a block diagram showing a delay fixing loop circuit according to the present invention.

FIG. 3 is a structure diagram showing a delay line adjustment circuit 200 of FIG. 2 in detail.

FIG. 4 is a structure diagram showing a phase comparison unit 300 of a blind pull control type and a delay line control unit 340 of a blind pull control type in detail.

FIG. 5 is a circuit diagram showing one example of a specific structure of a control circuit 420 of FIG. 4.

FIGS. 6a and FIG. 6b are the circuit diagrams showing one example of a specific structure of a control circuit 460 of FIG. 4, respectively.

FIG. 7 is a diagram for explaining the operations of a delay line 110 when the delay fixing loop of the present invention is an off state.

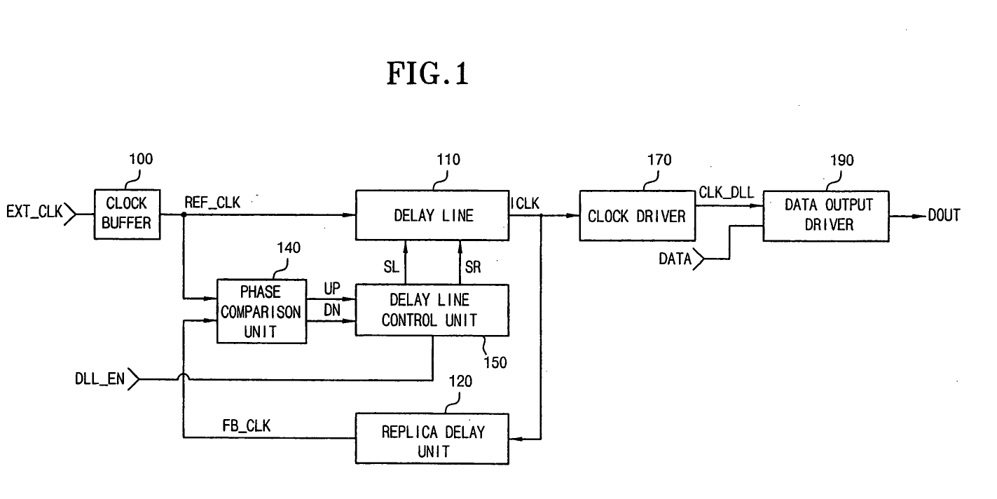

### DESCRIPTION OF SPECIFIC EMBODIMENTS

Hereinafter, exemplary embodiments of the present invention will be described with reference to the accompanying drawings.

The delay fixing loop circuit of the present invention can sufficiently secure a valid window of a data which is synchronized with an output clock of the delay fixing loop and is outputted when minimizing a delay level of the output clock of the delay fixing loop if the delay fixing loop is in a disable state.

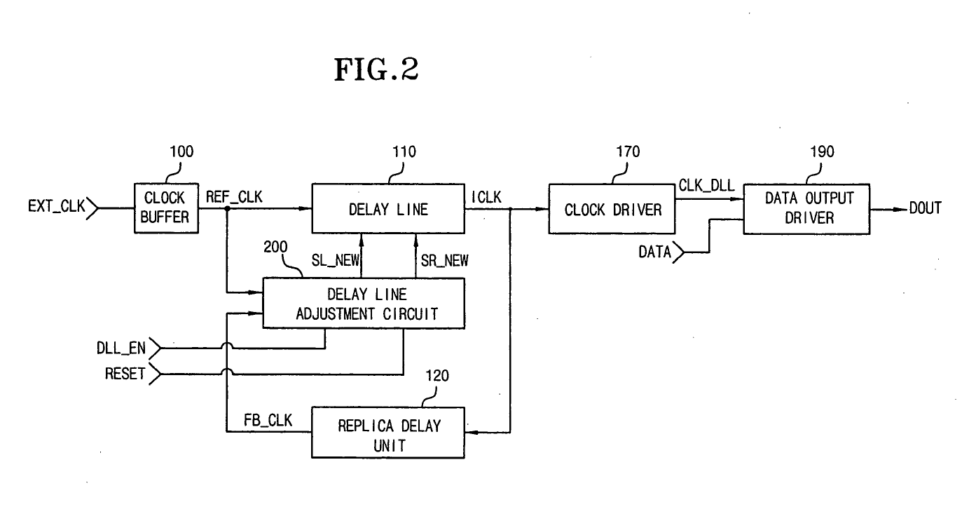

Referring to FIG. 2, a semiconductor memory device of the present invention includes a clock buffet 100, a delay line 110, a replica delay unit 120, a delay line adjustment circuit (DLAC) 200, a clock driver 170, and a data output driver 190.

The clock buffer 100 outputs a reference clock REF_CLK, and the reference clock REF_CLK is generated by buffering an external clock EXT_CLK.

The delay line 110 outputs an internal clock ICLK and the internal clock ICLK is generated by delaying the reference clock REF_CLK. The reference clock REF_CLK is delayed according to a delay amount which is set at an initial operation, and in the subsequent operations, the delay of the reference clock REF_CLK is adjusted by delay line adjustment circuit 200.

The replica delay unit 120 outputs a feedback clock FB_CLK, and the feedback clock FB_CLK is generated by replica-delaying the internal clock outputted from the delay line 110. Here, the replica delay of the replica delay unit 120 is set by modelling a delay time required for the external clock EXT_CLK to pass through the clock buffer 100 and to be outputted as the reference clock REF_CLK; and a delay time required for the internal clock ICLK to pass through the clock driver 170, to be synchronized with a data, and then to be outputted as a pad.

The delay line adjustment circuit 200 compares the reference clock REF_CLK and the phase of the feedback clock FB_CLK, and generates a shift left signal SL_NEW controlling a delay increase, and a shift right signal SR_NEW controlling a delay decrease signal. If the delay fixing loop is in an OFF state, only the shift right signal SR_NEW is enabled by an enable signal DLL_EN of the delay fixing loop and a reset signal RESET.

Here, the enable signal DLL_EN of the delay fixing loop becomes an ON state when the delay fixing loop is controlled to be in an enabled state, and the enable signal DLL_EN of the delay fixing loop becomes an OFF state when the delay fixing loop is controlled to be in a disable state. The reset signal RESET is a signal generating pulses if the delay fixing loop is in a disable state.

ON/OFF and reset of the delay fixing loop are generally specified in an expansion mode register set(EMRS) and a mode register set(MRS) which are supported in a semiconductor memory device. As one example, ON/OFF of the delay fixing loop is controlled according to the states of a specific external address under a state that an expansion mode register set(EMRS) is set, and reset of the delay fixing loop is controlled according to the states of a specific external address under a state that a mode register set(MRS) is set.

The signals generated by an expansion mode register set(EMRS) and a mode register set(MRS) can be provided to the delay fixing loop of the present invention as the enable signal DLL_EN of the delay fixing loop and the reset signal RESET. On the other hand, the delay fixing loop of the present invention can use the enable signal DLL_EN of the delay fixing loop and the reset signal RESET generated by other external and internal signals instead of EMRS and MRS.

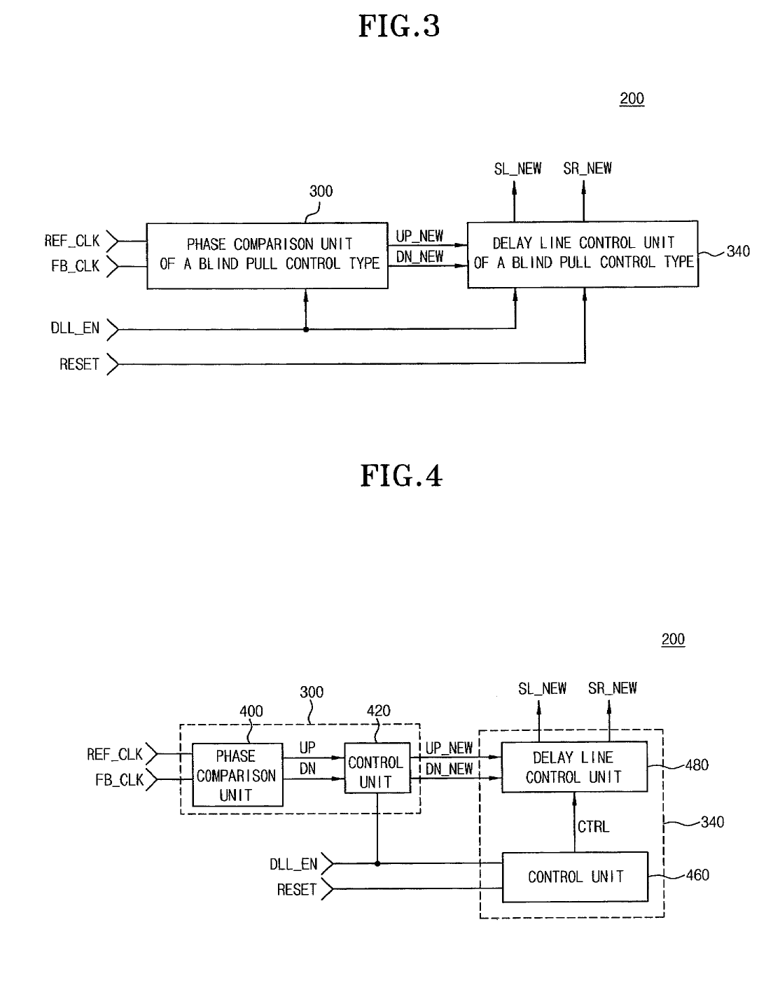

As shown in FIG. 3, the delay line adjustment circuit 200 includes a phase comparison unit 300 of a blind pull control type and a delay line control unit 340 of a blind pull control type. The structures are explained below.

The phase comparison unit 300 of a blind pull control type compares the reference clock REF_CLK and the phase of the feedback clock FB_CLK, and generates a delay increase signal UP_NEW and a delay decrease signal DN_NEW. The output of the phase comparison unit 300 is controlled according to the states of the enable signal DLL_EN of the delay fixing loop.

The delay line control unit 340 of a blind pull control type generates a shift left signal SL_NEW and a shift right signal SR_NEW as the output signals of phase comparison unit 300 of a blind pull control type, and the operations are controlled according to the states of the enable signal DLL_EN of the delay fixing loop and the reset signal RESET.

Further, specifically, the phase comparison unit 300 of a blind pull control type and the delay line control unit 340 of a blind pull control type can be configured as shown in FIG. 4.

Referring to FIG. 4, the phase comparison unit 300 of a blind pull control type includes a phase comparison unit 400 and a control unit 420, and the delay line control unit 340 of a blind pull control type includes a control unit 460 and a delay line control unit 480.

The phase comparison unit 400 compares the reference clock REF_CLK and the phase of the feedback clock FB_CLK, and outputs the delay increase signal UP and the delay decrease signal DN and the control unit 420 disables the delay increase signal UP_NEW corresponding to the delay increase signal UP, and enables the delay decrease signal DN_NEW corresponding to the delay decrease signal DN.

Further, the control unit 480 outputs a control signal CTRL by combining the enable signal DLL_EN of the delay fixing loop and the reset signal RESET. The delay line control unit 480 is operated in response to the control signal CTRL, and generates a shift left signal SL_NEW and a shift right signal SR_NEW as an output signal of the phase comparison unit 300 of a blind pull control type.

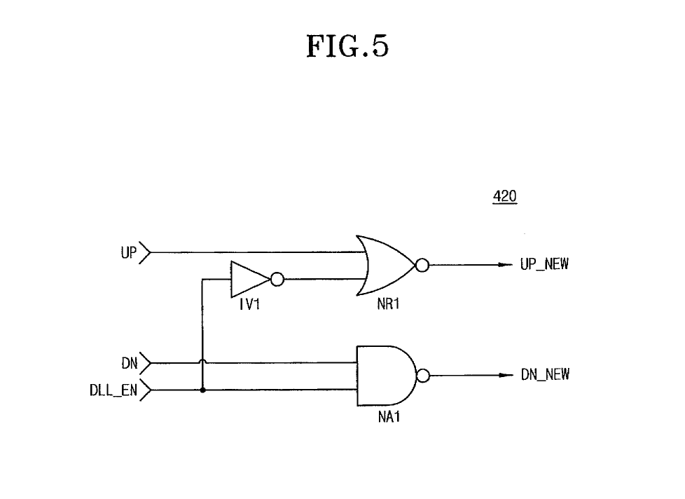

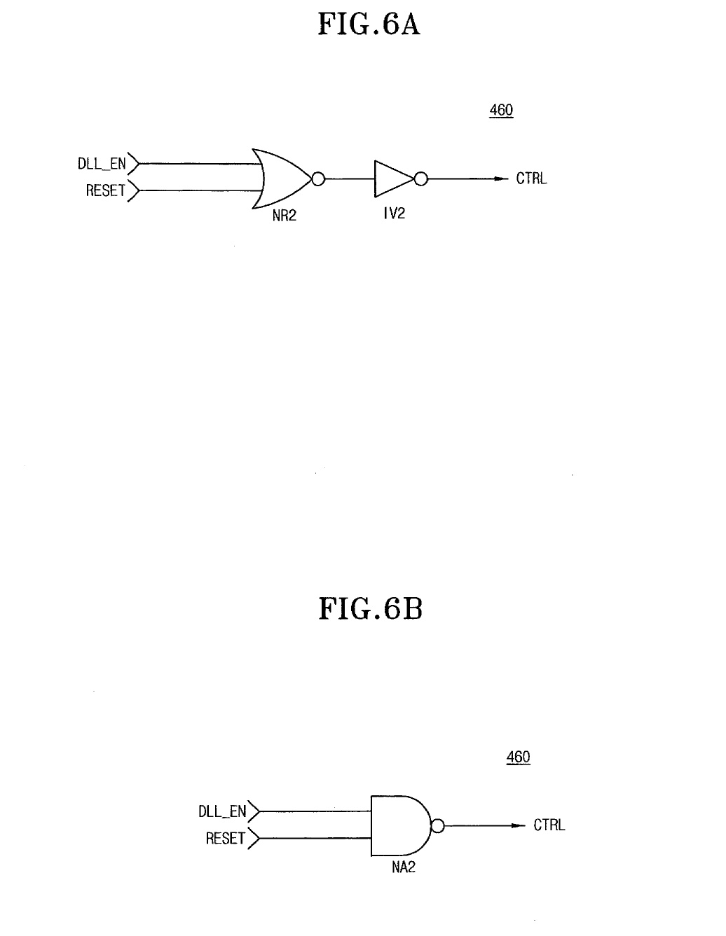

The control unit 420 controlling the output of the phase comparison unit 400 can be formed like an example shown in FIG. 5, and the control unit 480 controlling the operations of the delay line control unit 480 like an example shown in FIG. 6a and FIG. 6b.

That is, as shown in FIG. 5, the control unit 420 can consist of an inverter IV1 inverting the enable signal DLL_EN of the delay fixing loop, a NOR gate NR1 outputting the delay increase signal UP NEW by applying a NOR operation on the delay increase signal UP and the output signal of the inverter IV1, and a NAND gate NA1 outputting the delay decrease signal DN_NEW by applying a NAND operation on the enable signal DLL_EN of the delay fixing loop and the delay decrease signal DN.

As shown in FIG. 6a, the control unit 460 can consist of a NOR gate NR2 applying a NOR operation on the enable signal DLL_EN of the delay fixing loop and the reset signal RESET; and an inverter IV2 inverting the output signal of the NOR gate NR2, and outputting it as the control signal CTRL.

Further, as shown in FIG. 6b, the control unit 460 can consist of a NAND gate NA2 applying a NAND operation on NOR operation on the enable signal DLL_EN of the delay fixing loop and the reset signal RESET.

On the other hand, if the delay line 110 is locked by the delay line adjustment circuit 200, the driver 170 amplifies the internal clock CLK, and then outputs the amplified clock as the output clock CLK_DLL of the delay fixing loop.

Further, the data output driver 190 synchronizes the data DATA with the output clock CLK_DLL of the delay fixing loop and then outputs the synchronized data as the output data DOUT.

The semiconductor memory device of the present invention having such a structure outputs the output clock CLK_DLL of the delay fixing loop having a phase which is identical that of the external clock EXT_CLK by delaying and fixing the reference clock REF_CLK according to the comparison results of the reference clock REF_CLK and the phase of the feedback clock FB_CLK when the delay fixing loop is in an ON state like a conventional technology.

First of all, the delay time required for the external clock EXT_CLK to pass through the buffer clock 100 and then to be outputted as the reference clock REF_CLK is defined as “D1”, and the delay time required for the internal clock ICLK to pass through the clock driver 170, to be synchronized with a data, and then to be outputted as a pad is defined as “D2”. Then, the semiconductor memory device of the present invention delays the reference clock REF_CLK via the delay line 110 by the time obtained by substracting “D1+D2” from one period of the external clock EXT_CLK, and thereby can perform adjustment so that the output clock CLK_DLL of the delay fixing loop and the external clock EXT_CLK can have same phases.

On the contrary, when a memory chip is operated at a low speed, or the operations of the delay fixing loop are not required since a clock frequency is changed into a low frequency for reducing a power consumption, delay of the reference clock REF_CLK is minimized based on the enable signal DLL_EN of the delay fixing loop and the reset signal RESET, and is outputted as the output clock CLK_DLL of the delay fixing loop.

In this way, when the delay fixing loop of the present invention is in an OFF state, the operations of the delay fixing loop will be explained as follows. First of all, the phase comparison unit 400 compares the reference clock REF_CLK and the phase of the feedback clock FB_CLK, and determines the states of the delay increase signal UP and the delay decrease signal DN.

As an example, the delay increase signal UP is enabled if a rising edge of the feedback clock FB_CLK progresses in advance on the basis of a predetermined rising edge of the reference clock REF_CLK, and the delay decrease signal DN is enabled if a rising edge of the feedback clock FEB_CLK lags behind.

Further, the delay control unit 420 transmits the output of the phase comparison unit 400 to the delay line control unit 480 as it is when the delay fixing loop of the present invention is in an ON state.

On the contrary, the control unit 420 disables the delay increase signal UP_NEW corresponding to the delay increase signal UP, and enables the delay decrease signal DN_NEW corresponding to the delay decrease signal DN regardless of the output of the phase comparison unit 400 when the delay fixing loop of the present invention is in an OFF state.

On the other hand, the delay line control unit 480 is operated differently according to the control signal CTRL, and the operations of the delay line control unit 480 which is controlled by the control unit 460 having a structure shown in FIG. 6a and FIG. 6b will be explained as follows.

First of all, when the control unit 460 is configured as shown in FIG. 6a, if the delay fixing loop of the present invention is in an OFF state, the delay line control unit 480 disables both of the shift left signal SL_NEW and the shift right signal SR_NEW according the control of the control unit 460. That is, if the enable signal DLL_EN of the delay fixing loop is disabled, the control signal CTRL outputted from the control unit 460 is disabled and thus, the delay line control unit 480 becomes an OFF state.

Further, if the reset signal RESET is enabled while the enable signal DLL_EN of the delay fixing loop is disabled, the control signal CTRL outputted from the control unit 460 is enabled and thus, the delay line control unit 480 is operated. Thus, the states of the shift left signal SL_NEW and the shift right signal SR_NEW are determined according to the delay increase signal UP_NEW and the delay decrease signal DN_NEW provided from the control unit 420.

That is, since the control unit 460 enables the delay decrease signal DN_NEW while the delay fixing loop is in an OFF state, if the reset signal RESET is enabled under this state, the delay line control unit 480 receives the delay increase signal UP_NEW of an enable state and then enables the shift right signal SR_NEW.

The enable state of the shift right signal SR_NEW is maintained while the reset signal RESET is enabled, and the delay amount of the delay line 110 reduces continuously while the shift right signal SR_NEW is enabled.

Next, when the control unit 460 is configured as shown in FIG. 6b, if any one of the reset signal RESET and the enable signal DLL_EN of the delay fixing loop is enabled, the control signal CTRL outputted from the control unit 460 is disabled and thus, the delay line control unit 480 becomes an OFF state.

Further, if both of the reset signal RESET and the enable signal DLL_EN of the delay fixing loop are disabled, the control signal CTRL outputted from the control unit 460 is enabled and thus, the delay line control unit 480 is operated. Thus, the states of the shift left signal SL_NEW and the shift right signal SR_NEW are determined according to the delay increase signal UP_NEW and the delay decrease signal DN NEW provided from the control unit 420.

In this way, the control unit 460 enables the reset signal RESET if the enable signal DLL_EN of the delay fixing loop is in a disable state, and enables the control signal CTRL if both of the reset signal RESET and the enable signal DLL_EN of the delay fixing loop are disabled.

Further, the delay line control unit 480 determines an enable of the shift left signal SL_NEW and the shift right signal SR_NEW according to the states of the control signal CTRL.

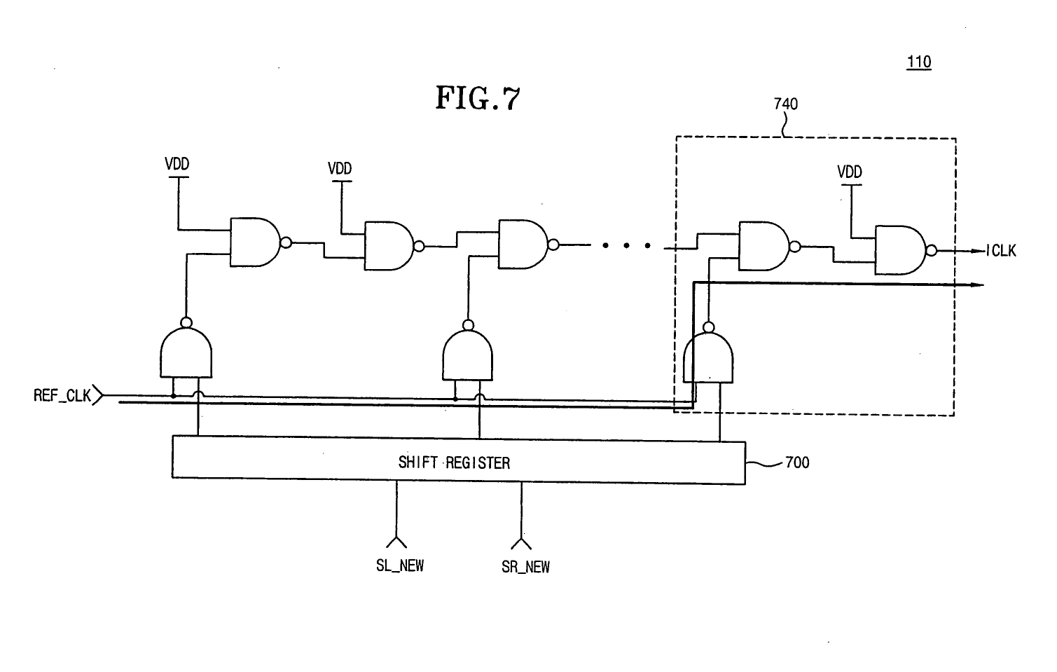

Referring FIG. 7, while the enable signal DLL_EN of the delay fixing loop is disabled and the control signal CTRL is enabled, the operations of the delay line 110 will be explained as follows. When the delay line 110 is configured by a plurality of unit delay sections as shown in FIG. 7, an output of a shift register 700 shifts to a direction in which the delay is reduced while the shift right signal SR_NEW is maintained as an enable state.

Further, after a predetermined time, only a unit delay section 740 connected to the output stage is enabled by the shift register 700, and the reference clock REF_CLK is delayed by the delay amount of the unit delay section 740, and then is outputted as the internal clock ICLK.

That is, while the delay fixing loop is an OFF state, and the control signal CTRL is enabled, the delay line 110 reduces the delay amount of the reference clock REF_CLK, and finally shifts the reference clock REF_CLK to the shortest path as shown by an arrow direction of FIG. 7. Accordingly, if the delay fixing loop is an OFF state, the reference clock REF_CLK is locked by a minimum delay amount and then is outputted as the internal clock ICLK.

As explained above, while the control signal CTRL is enabled, when an operation of the delay fixing loop is not necessary, the semiconductor memory device of the present invention locks the reference clock REF_CLK by the minimum delay amount and outputs it as the output clock CLK_DLL of the delay fixing loop.

When data is synchronized with the output clock CLK_DLL of the delay fixing loop which is delayed to the minimum, and the synchronized result is outputted to outside, since a data output having a constant tAC can be guaranteed, even though the delay fixing loop is in an OFF state, there is an effect that sufficient valid windows of data can be secured.

In this way, according to the present invention, when a particular operation mode of a memory is entered, since the operations of the delay fixing loop are not necessary, if the delay fixing loop is in an OFF state, the output clock of the delay fixing loop which controls a data output is controlled such that it is locked by a minimum delay, and then is outputted, and thereby there is an effect that sufficient valid windows of data can be secured.

Until now, the present invention is explained with referring to the specific embodiments, but the present invention is not limited to them, and it is to be noted that various modifications and changes can be realized by the person in the art to which the present invention belongs without deviating the scope of the present invention, which is claimed in the claims illustrated as below within the spirit of the present invention.

What is claimed is:

1. A delay fixing loop circuit, comprising:
a delay circuit delaying a reference clock in which an external clock is buffered and outputting the delayed reference clock as an internal clock;
a control circuit comparing the reference clock and a phase of a feedback clock of the internal clock, and increasing or decreasing delay of the reference clock of the delay circuit according to the comparison result if a delay fixing loop is in an enable state, and decreasing delay of the reference clock of the delay circuit according to a reset signal provided from outside if the delay fixing loop is in a disable state; and
a clock driver providing the internal clock of the delay circuit which is controlled by the control circuit as an output clock of the delay fixing loop.

2. The delay fixing loop circuit set forth in claim 1, wherein an operation of the delay fixing loop is disabled in response to a mode in which an operation clock frequency is changed into a low frequency.

3. The delay fixing loop circuit set forth in claim 1, wherein an enable state and a disable state of the operation of the delay fixing loop are determined according to a state of an external address provided under a state that an expansion mode register set(EMRS) is set.

4. The delay fixing loop circuit set forth in claim 1, wherein a state of the reset signal is determined according to the state of the external address provided under a state that a mode register set(MRS) is set.

5. The delay fixing loop circuit set forth in claim 1, wherein the control circuit comprises:
a replica delay unit replica-delaying the internal clock and outputting it as the feedback clock; and
a delay line adjustment circuit comparing the reference clock and the phase of the feedback clock of the internal clock, and increasing or decreasing delay of the reference clock of the delay circuit according to the comparison result if the delay fixing loop is in an enable state, and decreasing delay of the reference clock of the delay circuit according to the reset signal provided from outside if the delay fixing loop is in a disable state.

6. The delay fixing loop circuit set forth in claim 5, wherein the delay line adjustment circuit comprises:
a phase comparison unit of a blind pull control type comparing the reference clock and the phase of the feedback clock, and generating a delay increase signal and a delay decrease signal if the delay fixing loop is in an enable state, and generating the delay decrease signal if the delay fixing loop is in a disable state; and
a delay line control unit of a blind pull control type generating a shift left signal and a shift right signal corresponding to the delay increase signal and the delay decrease signal, respectively, and controlling a delay increase or a delay decrease if the delay fixing loop is in an enable state, and generating the shift right signal corresponding to the delay decrease signal according to the reset signal, and controlling the delay decrease if the delay fixing loop is in a disable state.

7. The delay fixing loop circuit set forth in claim 6, wherein the phase comparison unit of a blind pull control type comprises:
a phase comparison unit comparing the reference clock and the phase of the feedback clock and outputting the delay increase signal and the delay decrease signal; and
a first control unit disabling the delay increase signal, and enabling the delay decrease signal if the delay fixing loop is in a disable state.

8. The delay fixing loop circuit set forth in claim 7, wherein the phase comparison unit enables the delay increase signal if a rising edge of the feedback clock goes in advance on the basis of a predetermined rising edge of the reference clock, and enables the delay decrease signal if a rising edge of the feedback clock lags behind.

9. The delay fixing loop circuit set forth in claim 6, wherein the delay line control unit of a blind pull control type comprises:
a second control unit outputting a control signal according to the reset signal if the delay fixing loop is in a disable state; and
a delay line control unit operating according to a state of the control signal, and generating and the shift left signal and the shift right signal as output signals of the phase comparison unit of a blind pull control type.

10. The delay fixing loop circuit set forth in claim 9, wherein the second control unit enables the control signal if the delay fixing loop is in a disable state, and determines an enable state of the control signal according to the state of the reset signal if the delay fixing loop is in a disable state.

11. The delay fixing loop circuit set forth in claim 10, wherein the delay line control unit operates when the control signal is enabled; enables the shift left signal if the delay increase signal is provided to the phase comparison unit of a blind pull control type; and enables the shift right signal if the delay decrease signal is provided to the phase comparison unit of a blind pull control type.

12. The delay fixing loop circuit set forth in claim 11, wherein the delay circuit increases a delay amount of the reference clock if the shift left signal is enabled, and decreases the delay amount of the reference clock if the shift right signal is enabled.

13. The delay fixing loop circuit set forth in claim 12, wherein the delay circuit includes a plurality of unit delay sections which are serially connected and are controlled by the shift left signal and the shift right signal; and only a unit delay section connected to an output stage among the plurality of unit delay sections is enabled according to the shift right signal if the delay fixing loop is in a disable state.

14. The delay fixing loop circuit set forth in claim 9, wherein the second control unit enables the control signal if any one of the reset signal and the delay fixing loop is in an enable state, and disables the control signal if both of the reset signal and the delay fixing loop are in an enable state.

15. A clock locking method of a delay fixing loop circuit, comprising:
a first step generating a reference clock by buffering an external clock;
a second step delaying the reference clock and outputting it as an internal clock;
a third step comparing the reference clock and a phase of a feedback clock of the internal clock, and increasing or decreasing delay of the reference clock of the delay circuit according to the comparison result if a delay fixing loop is in an enable state, and decreasing delay of the reference clock of the delay circuit according to a reset signal provided from outside if the delay fixing loop is in a disable state; and
a fourth step providing the internal clock in which delay is controlled by operation of the delay fixing loop and the reset signal as an output clock of the delay fixing loop.

16. The clock locking method of a delay fixing loop circuit set forth in claim 15, wherein operation of the delay fixing loop is disabled in response to a mode in which an operation clock frequency is changed into a low frequency for reducing a low speed operation mode and a power consumption.

17. The clock locking method of a delay fixing loop circuit set forth in claim 15, wherein an enable state of the operation of the delay fixing loop are determined according to a state of an external address provided under a state that an expansion mode register set(EMRS) is set.

18. The clock locking method of a delay fixing loop circuit set forth in claim 15, wherein a state of the reset signal is determined according to the state of the external address provided under a state that a mode register set(MRS) is set.

19. The clock locking method of a delay fixing loop circuit set forth in claim 15, wherein if the delay fixing loop is in an enable state, the third step executes a step comparing the reference clock and the phase of the feedback clock, and generating a delay increase signal and a delay decrease signal; and a step generating a shift left signal and a shift right signal corresponding to the delay increase signal and the-delay decrease signal, respectively, and controlling a delay increase or a delay decrease of the second step; and
if the delay fixing loop is in a disable state, the third step executes a step generating the delay decrease signal; and a step generating the shift right signal corresponding to the delay decrease signal according to the reset signal, and controlling the delay decrease of the second step.
